(19) United States
(12) Patent Application Publication
(10) Pub. No.: US 2025/0067646 A1
(43) Pub. Date: Feb. 27, 2025

(54) APPARATUS AND METHOD FOR CAPTURING CHANGES IN POSITION OF AT LEAST ONE COMPONENT MOUNTED IN AN ASSEMBLY

(71) Applicant: Urs TSCHUDIN, Grenchen (CH)

(72) Inventor: Alain GEISER, Murten (CH)

(73) Assignee: Urs TSCHUDIN, Grenchen (CH)

(21) Appl. No.: 18/810,739

(22) Filed: Aug. 21, 2024

(30) Foreign Application Priority Data
Aug. 22, 2023 (EP) 23192673.4

(51) Int. Cl. G01N 3/06; G01N 3/32; G04B 45/00

(52) U.S. Cl. CPC G01N 3/068; G01N 3/32; G04B 45/0076; G01N 2203/0647

(57) ABSTRACT

In an apparatus and a method for capturing changes in position of at least one component mounted in an assembly, the assembly is positioned in the apparatus and a camera is calibrated. An image of the assembly is recorded before the assembly is subjected to the vibration. The assembly is exposed to vibrations for a defined period of time and intensity. An image of the assembly is recorded after the assembly is subjected to the vibration. The two images are superposed on one another with the aid of an image processing device, and differences are identified. The results are displayed on a display, wherein possibly the components with changes in position (or possibly those without changes) are highlighted visually. The user examines the results and can then take further actions on the basis of the changes in position detected.

### CROSS REFERENCE TO RELATED APPLICATIONS

Applicant claims priority under 35 U.S.C. § 119 of European Application No. 23192673.4 filed Aug. 22, 2023, the disclosure of which is incorporated by reference.

### BACKGROUND OF THE INVENTION

### 1. Field of the Invention

The present invention relates to an apparatus and a method for capturing changes in position of at least one component mounted in an assembly.

### 2. Description of the Related Art

Assemblies consisting of a number of individual components that are mounted in a fixed positional relationship to each other fulfil a critically function in many branches of industry. Ensuring that the fixed positional relationship and stability of the individual components are maintained in an assembly has various important effects.

On the one hand, the correct positioning of the components is decisive for the proper functioning of the unit as a whole. In the automobile industry, for example, engine parts must be assembled with the greatest of precision in order to guarantee that the engine will function efficiently and with maximum possible power. In the electronics industry, printed circuit boards and components must be positioned correctly to ensure that electrical connections are made.

On the other hand, in many cases the aesthetic quality of the positionally secure connection of components in an assembly is also very important, particularly in the consumer goods industry or in public applications. Precise installation and positional relationship make for an attractive presentation and deliver a professional impression.

For this purpose, the orientation and position of the components in the assembly are fixed with suitable joining methods (form fitting, force fitting and/or bonding). But despite careful manufacturing and quality monitoring, deficiencies inherent in the manufacturing process can still result in variations in the joint strength of the individual components of an assembly. Over the course of the assembly's service life, these variations can lead to undesirable changes in the position of individual components, ultimately even the complete detachment of individual components from the assembly.

The effects of these deficiencies can take many forms. When components shift or become detached due to loose connections, this can cause malfunctions or even complete breakdown of the finished product. In critical applications such as medical or aerospace engineering, malfunctions of this kind can have grave consequences. In assemblies in which the external presentation is important, such as consumer goods or architecture, for example, loose or displaced components can impair the aesthetic quality and affect the overall appearance.

The above-mentioned problem of ensuring a high level of aesthetic quality at all times is of crucial importance, especially in the jewellery and watchmaking industry, and particularly in the case of expensive, luxury watches. After all, luxury watchmakers often rely on their brand and reputation as a main selling point, and the aesthetic quality of the watches is closely bound up with the perception of the brand.

Diamonds and other gemstones are commonly used in the watchmaking industry, particularly in luxury watches, to enhance their appearance, prestige and value. Gemstones can lend a particular aesthetic to the dial, the crown or the case of a watch, which sets it apart from other watches. The challenge consists in ensuring that these gemstones are seated securely and firmly in watch cases, crowns and dials and do not come loose or shift over time.

In order to fix the gemstones securely and firmly in the watches, various techniques are used, and one of these is the use of claws. The four-claw setting is a method commonly used in the jewellery and watchmaking industry for fastening solitaire gemstones. Accordingly, for example, four claws are attached around each hole in the crown of the watch to hold a stone firmly in place and at the same time enable it to refract the light in a way that maximizes its brilliance.

The use of small, irregularly cut diamonds of different sizes or small facets poses a further challenge. The irregular shape of the diamonds demands precise adaptations of the claws to ensure that the gemstones are held securely and cannot come loose.

Watchmakers and jewellery designers must take care that the claws are bent evenly and securely around the gemstone, but without damaging the stone. They must also ensure that the gemstones are positioned evenly in the dial or the crown in order to guarantee a balanced, attractive overall appearance.

In the jewellery and watchmaking industry, the work of stone setting is often still done by hand in large factory buildings by many expert artisans. Gemstone setting requires a high level of manual precision and care, and working under a microscope with powerful magnification enables the experts to see the fine details and place the gemstones in the jewellery pieces safely and with an aesthetically satisfactory way.

In the manufacture of high-value, luxury watches, the gemstones are first fitted into the metal settings, and then held securely in place with the small, malleable metal claws or prongs that clasp the stones from different sides. When the stones have been seated in their settings, the part of the watch in which the stones are seated (the crown device for example) is viewed under a microscope. This enables a highly precise examination of the positioning of each individual stone. In order to test the strength of the setting, a jet of compressed air is directed at the stones. This jet of air is blown in different directions in order to test the stability of the stones in the claws. If a stone seems easy to move or loose, it is marked. When a stone has been identified as loose or not secure, the entire watch part (the crown device for example) must be returned to production, where the stone in question is reset. The setting is opened by carefully loosening the claws, the loose stone is removed, the setting is reworked, and the stone is placed in the setting again, securely and firmly.

Even though the method with the claws and the compressed air test is a widely used and proven practice for fastening gemstones in items of jewellery (such as wristwatches) and testing their positional stability, there are still potential problems.

Although the compressed air jet is useful as a preliminary aid in testing the stability of the stones in the setting, it cannot simulate all possible routine situations and stresses to which an item of jewellery might be exposed. In practice, jewellery items may be subject to a variety of stresses that far exceed those represented by simply blasting them with compressed air. In particular, repetitive impacts or concussions (vibrations) may adversely affect the stones' stability. A stone which at first seems stable under the force of the air jet might become loose or move under such real-life conditions.

### SUMMARY OF THE INVENTION

It is therefore the object of the present invention to provide an apparatus and a method for capturing changes in position of at least one component mounted in an assembly, which is able to preserve the desired functionality and aesthetic quality of the assembly simply and by automated means (without unavoidable manual intervention).

This object is solved with regard to the apparatus for capturing changes in position of at least one component mounted in an assembly with an apparatus having the features according to one aspect of the invention, and with regard to the method for capturing changes in position of at least one component mounted in an assembly with a method having the features according to another aspect of the invention.

Further advantageous variants of the apparatus according to the invention and the method according to the invention are discussed below.

In detail, an apparatus according to the invention for capturing changes in position of at least one component mounted in an assembly comprises: at least one vibration generator for subjecting the assembly to vibration movements; at least one image capturing device for capturing images of the same partial or total view of the assembly in which the at least one component is mounted, before and after the assembly is subjected to vibration movements; an image processing device for superimposing the images captured before and after the assembly is subjected to vibration movements; and an image reproduction device for reproducing the superimposed images, with visual highlighting of one or more components that have either undergone changes in position or have not undergone changes in position.

The apparatus according to the invention uses vibrations or vibration movements to determine changes in the position of components in an assembly. In contrast to firmly mounted components, components that are not securely mounted or are possibly damaged will move due to the vibrations transmitted to the assembly and will consequently be in different positions after the vibration loading is carried out compared with before the vibration loading is carried out. In order to fulfil the function of capturing the described changes in position, the apparatus according to the invention consists of several cooperating components (vibration generator, image capturing device, image processing device and image reproduction device).

The superimposing of images before and after the exposure to vibration intended according to the invention may be implemented in the measuring instrumentation and quality control to visualize and analyze possible shifts or movements of components in an assembly.

An apparatus according to the invention may be operated as follows: First, the assembly to be examined is positioned in the apparatus, and the image capturing device (for example a camera) is calibrated. Then, high-resolution images of the assembly are captured before the vibration is applied. These serve as reference images, representing the starting positions of the components. The assembly is subjected to a controlled vibration load (with defined duration and intensity). This may be carried out by various methods, such as mechanical excitation, vibrations or similar processes. After the vibration loading, images of the assembly are captured again. These images represent the current positions of the components after the loading. The images before and after the vibration loading are superimposed on each other. This is performed either manually using image processing software or automatically with the aid of special image registration algorithms. The superposition renders the shifts or changes in position of the components visible. Components whose position has not changed remain completely congruent in the superposition and appear unchanged. On the other hand, components that have shifted or moved are highlighted by offsets in the superposition. Various techniques can be employed to make the differences more clearly visible, such as the use of color or brightness changes in the superimposed images. The highlighted regions show the positions of the components that have changed compared with the reference images.

This image superposition and the visual highlighting makes it easier to identify potential problems or deviations in the assembly. The technique enables rapid, effective quality control, fault diagnosis or status monitoring of assemblies in various technical applications and can be helpful in various sectors such as the automobile industry, aerospace engineering, electronics manufacturing or other fields in which the precision and stability of assemblies is very important.

Image processing and the application of visual highlights offer many advantages for the purpose of analyzing position changes in assemblies. At the same time, the quality of the captured images is important for exact results. Clear, high-resolution images minimize possible errors during image processing and increase the accuracy of the position determination.

A particularly preferred embodiment of the apparatus according to the invention further comprises a microscope, wherein the image capturing device is provided either in place of a microscope eyepiece or immediately behind a microscope eyepiece in order to capture the magnified images generated by the microscope.

The integration of a microscope in the apparatus represents a notable addition, particularly when it is important to perform detailed examinations of assemblies or components that require strong magnification. Providing the image capturing device in place of the microscope eyepiece or immediately behind the eyepiece enables magnified images that are generated by the microscope to be captured and processed further.

Integration of the microscope in the apparatus offers various advantages. Thus, microscopes make it possible to view components or structures with very high magnifications, which is often essential to enable the analysis of tiny details or microstructures. The powerful magnification of the microscope enables an exact evaluation of the smallest changes in position or shifts in the assembly. The magnification can make even tiny changes in the orientation of components or microstructures visible, which are barely detectable with the naked eye. The apparatus may be used both for macroscopic and microscopic examinations, depending on the requirements for the specific assembly or component. The recording of the magnified images means that the results can be documented and analyzed in detail later, which supports troubleshooting and process optimization.

In a preferred further development of the aforementioned embodiment, the microscope includes a carrier unit for the assembly, wherein the carrier unit is coupled to the vibration generator mechanically, electrically or electromechanically, or the vibration generator is integrated in the carrier unit.

The microscope is thus a particular kind of “shaking microscope”, which is capable of subjecting the assembly or sample to be examined to mechanical oscillations before, during and after the observation. This vibration excitation makes it easier to observe and analyze certain effects or behaviors of the assembly, in particular when dynamic or resonant phenomena are of interest.

In the case of mechanical coupling, the carrier unit on which the assembly for examination is placed is connected to an external vibration generator via mechanical components. The vibration generator may be for example a vibration platform or an electromechanical excitation body that is capable of generating precise oscillations. In the case of electrical coupling, the vibration is excited by electrical signals that are transmitted to the carrier unit. The carrier unit may be equipped with electromagnetic actuators or piezoelements, which produce vibrations when an electrical voltage is applied. The electromechanical coupling is a combination of mechanical and electrical coupling. If the vibration generator is integrated directly in the microscope carrier unit, a compact, readily controllable solution for generating vibrations before, during and after the observation may be obtained.

Additionally, a preferred embodiment of the apparatus according to the invention further includes at least one illuminating device for illuminating the partial or complete view of the assembly reproduced by the image capturing device.

Selective illumination enables certain features or structures in the assembly to be highlighted, which makes it easier to identify changes in position. Selective illumination can also improve the quality and informative value of the superimposed images, which in turn increases the accuracy and efficiency of the position change analysis.

Integration of an illuminating device in the apparatus may thus lead to a further improvement in the quality and precision of the results. This is particularly important when fine details or subtle changes in the assembly must be captured. The combination of vibration generator, image capturing device, image processing device and illuminating device transforms the apparatus into a powerful tool for the analysis and quality control of position changes in assemblies and components.

With the aforementioned embodiment, it may also be provided that the illumination carried out by the illuminating device is adjusted in such a way that during superposition of the images, which is carried out by the image processing device and reproduced by the image reproduction device, a black background is created, against which only the image areas that have either undergone changes in position or undergone no changes in position, are highlighted visually as bright image areas.

This setting of the illuminating device in order to create a black background when the images are superimposed is highly advantageous. In particular, it produces a clear contrast, which allows the superimposed images to be visualized more effectively and the differences between the image areas that have undergone changes in position and those that have remained positionally stable to be highlighted clearly.

If the illuminating device has been adjusted in such a way that it creates a black background, the image areas created as bright image areas by the superposition carried out by the image processing device, are visible particularly clearly. In this way, the image areas that have undergone a change in position or have remained positionally stable, are highlighted in strong contrast against the black background.

When the two images are superposed, a differential image is created, for example. This means that for each pixel in the image the difference between the brightness values (or color values) of the two images is calculated. If both images match perfectly (that is to say they are congruent), the difference between the two images at each pixel is zero. If the representation of this “no difference” value is interpreted as black, a completely congruent image will appear entirely black. But if a deviation between the images is detected at any point (for example because of a change in the position of a component), this pixel will not be black, but instead will have a brightness and/or color value that reflects the degree of the deviation.

This makes it easy to identify even small changes visually. The image areas that show up brightly and/or in color make it easier to detect the shifts or movements of the components and enable rapid, efficient quality control. At the same time, the black background returns a clear, uncomplicated representation which facilitates the interpretation of the superimposed images.

Moreover, a particularly practical embodiment of the present invention provides that the vibration generator is embodied as a mechanical oscillator, a magnetoinductive oscillator, a pneumatic oscillator, a piezoelectric transducer or an electroacoustic transducer.

Each of these variants has its own properties and modes of operation for transmitting vibration movements to the assembly. A mechanical oscillator produces oscillations by mechanical movements, for example via a crank or an eccentric shaft. A magnetoinductive oscillator produces oscillations by electromagnetic induction, through the interaction of magnetic fields and electrical currents. A pneumatic oscillator produces oscillations with the aid of compressed air or other gases that are driven by a fan or pneumatic apparatus. A piezoelectric transducer produces oscillations by the piezoelectric effect, in which a piezoelectric material is deformed mechanically when an electrical voltage is applied to it. An electroacoustic transducer produces oscillations by converting electrical signals into sound waves. A suitable variant of the vibration generator can be implemented in the apparatus depending on the specific requirements and the components to be examined. The underlying operating principle of the apparatus remains the same, regardless of the type of vibration generator.

According to a further, particularly practical embodiment, the image capturing device is embodied as a camera, in particular a high-resolution digital camera, wherein the camera is movable in particular in order to set the desired view.

Through the use of a movable high-resolution digital camera, the apparatus is able to record the desired images of the assembly before and after the vibration movements, and thus also to precisely detect the changes in position of the components. The capability to move the camera offers flexibility in the recording of the images from various perspectives and makes it possible to scrutinize specific areas of the assembly more closely.

The image processing device may then superpose the images recorded by the camera, and the image reproduction device may reproduce the superposed images with visual highlighting of the components that have undergone changes in position or undergone no changes in position.

This variant thus allows a more exact, more comprehensive analysis of position changes in the assembly, thus offering an effective technique for monitoring and quality control of assemblies in various applications.

According to a further preferred embodiment of the invention, it is provided that the image reproduction device is embodied as a screen, in particular a high-resolution display.

The use of a high-resolution display enables a detailed, high-quality representation of the superposed images.

The image processing device superposes the images recorded before and after the vibration movements, and these superposed images are then reproduced on the high-resolution display. The visual highlighting of the components that have undergone position changes or have not undergone position changes, will be clearly visible on the display.

The use of a high-resolution display as image reproduction device enables a clear, precise representation of the changes in position, which in turn makes analysis and evaluation of the results easier. This is particularly important for enabling exact evaluations to be made and detecting possible deviations of problems in the connections of the assembly.

In detail, a method according to the invention for capturing changes in position of at least one component mounted in an assembly comprises: subjecting the assembly to vibration movements; recording images of the same partial or total view of the assembly in which the at least one component is mounted, before and after the assembly is subjected to vibration movements; superimposing the images recorded before and after the assembly is subjected to vibration movements; and reproducing the superimposed images with visual highlighting of one or more components that have either undergone changes in position or have not undergone changes in position.

The method steps in the method according to the invention described above substantially correspond to the functions of the apparatus components of the apparatus according to the invention described previously. The method according to the invention therefore possesses the same advantages as were explained in detail earlier in connection with the apparatus according to the invention.

The method according to the invention thus relies on a kind of differential image processing or image superposition to highlight changes in the positions of the components. This may be useful in particular for rendering movements or changes in an assembly visible, particularly if such movements are small or slight.

When the superposed images are reproduced, components that have either undergone changes in position or have not undergone changes in position are highlighted visually. The visual highlighting makes it easier to identify the components concerned and enables rapid inspection for any problems or deviations in the assembly.

In particular, the method according to the invention enables position changes in an assembly to be captured efficiently and precisely. It can be used in various applications, such as quality control, manufacturing and engineering research to monitor and analyze positional stability and the effects of vibrations on components.

The visual highlighting in the superposed images that are reproduced in an image reproduction device enables simple, unambiguous identification of a component that has undergone an undesirable position change, or which has not undergone a position change. This component may then be marked in the assembly. The marked component is then subjected to post-processing. The nature of the post-processing may vary according to the application. For example, a more comprehensive examination of the component may be carried out to determine whether the position change is indeed significant, or if it falls within a permitted tolerance. In some cases, the post-processing may also include a repair or realignment of the component in order to ensure correct positioning.

### DETAILED DESCRIPTION OF PREFERRED EMBODIMENTS

A particularly preferred embodiment of the apparatus according to the invention or the method according to the invention consists in that the assembly is a watchmakers' artefact, in particular a wristwatch, more particularly a crown device for a wristwatch, and the at least one component is a decorative element, in particular a jewel, more particularly a gemstone, and wherein the decorative element is retained in the watchmakers' artefact by multiple, in particular four, claws.

The method would proceed as described previously, wherein the wristwatch, in particular the crown device thereof, is exposed to vibration movements, wherein images of the partial or complete view of the wristwatch, in particular the crown device thereof, are recorded before and after vibration are applied thereto, wherein the images recorded before and after the vibration movements are superposed in order to render changes in the positions of the one or more decorative elements (gemstones) visible, and wherein the superposed images are reproduced on a high-resolution display with visual highlighting of the one or more decorative elements (gemstones) that have undergone undesirable changes in position.

Then, the corresponding decorative elements (gemstones) in the wristwatch, in particular in the crown device, are marked and undergo post-processing. Post-processing may include a more thorough examination of the one or more decorative elements (gemstones) to determine whether the position changes are significant, or if they fall within the permitted tolerances. Suitable measures may be implemented as necessary to reposition the one or more decorative elements (gemstones) correctly again, or optionally to repair or replace them and so ensure that the quality and aesthetic appearance of the wristwatch is maintained.

In an alternative variant of the apparatus according to the invention of the method according to the invention, it is provided that the assembly is an electrical or electronic assembly, in particular that it is an assembled printed circuit board, and the at least one component is an electrical or electronic component, in particular a component that is mounted on the surface of a printed circuit board.

The apparatus according to the invention and the method according to the invention may thus be applied to this alternative to detect and monitor undesirable changes in position of electrical or electronic components on an assembled printed circuit board. The surface of a printed circuit board may be equipped with a multiplicity of electrical or electronic components, according to the requirements and functions of the printed circuit board. These may include for exemplary purposes: resistors; capacitors; diodes; transistors; integrated circuits (ICs); LEDs; crystals and oscillators; and plug-in connectors.

In this case, the apparatus according to the invention and the method according to the invention offer an effective method for quality control and for testing positional stability in electrical or electronic assemblies. This is particularly important in order to ensure the reliable and faultless function of electrical or electronic devices. The visual highlighting enables simple identification of the components concerned and facilitates targeted analysis and post-processing.

Finally, it is provided in a further alternative variant that the assembly is an antifriction bearing, and the at least one component is a rolling element of the antifriction bearing.

Antifriction bearings are mechanical components that are used in many machines and mechanisms to reduce the friction between moving parts and enable low-friction movement. The rolling elements, which move between the inner and outer rings of the bearing, are the central element of the bearing and enable the low-friction movement. The rolling elements may be balls, rollers, cylinders or needles depending on the bearing type.

In the present context, the apparatus according to the invention and the method according to the invention are intended to identify “blocked” rolling elements which have incorrectly not undergone a change in position. Such “blocked” rolling elements might be limited in their movement due to dirt, damage or other factors, and thereby compromise the functionality and service life of the antifriction bearing.

The “blocked” rolling elements are highlighted visually in the superposed images by a suitable illumination. The “blocked” rolling elements are identifiable as such by superposition of the images of the antifriction bearing recorded before and after it is subjected to vibration, because they have not undergone a change of position as a result of the vibration loading.

The visual highlighting of the “blocked” rolling elements enables early detection of possible damage or problems in the antifriction bearing. Consequently, targeted servicing measures may be undertaken, or the rolling elements concerned may be replaced in order to increase the reliability and service life of the antifriction bearing and avoid machine failures.

The apparatus according to the invention and the method according to the invention offer particularly advantageous applications for watch crown devices for luxury wristwatches, in which the outer end face of the crown is furnished with precious stone applications. In high-value wristwatches, gemstones such as diamonds, sapphires or rubies are often worked into the crown device as decorative elements to achieve a sophisticated, luxurious aesthetic. The apparatus according to the invention and the method according to the invention enable precise, efficient monitoring of the positional stability of the gemstones in the crown device of the watch.

In this context, first a pin sharp image of the crown with gemstone applications is recorded using a “shaking microscope” equipped with a vibration generator, a camera, a processor for image processing and a display screen. Then, the crown is vibrated intensely (caused to vibrate) by mechanical means for several seconds. After the vibration, another image of the crown is recorded in order to document the changes in position of the gemstones caused by the vibration. The two recorded images (before and after the vibration) are superimposed on one another appropriately. The superimposed images are views on the screen of the “shaking microscope”. If the superposed images are completely congruent, the screen is entirely black. But if a gemstone has moved as a result of the vibration, this stone lights up in the superposed images and can be identified as a component that has moved. The gemstones that have moved may thus be highlighted visually using the “shaking microscope” and then marked manually in the crown device by the user. In this way, it is possible to perform post-processing selectively on the gemstones concerned, for example by repositioning or checking further for damage.

The apparatus according to the invention and the method according to the invention offer an extremely precise method for inspecting changes in position in watch crown devices with gemstone applications. They allow rapid, exact evaluation of the positional stability of the gemstones and make it easier to carry out targeted measures for maintaining the aesthetic and functional quality of luxury wristwatches. The high resolution and sensitive imaging of the “shaking microscope” enable detailed quality control and inspection for the purpose of ensuring the perfection and excellence of these high-value products.

A “shaking microscope” of this kind, which is able to generate vibration movements and at the same time is equipped with an image superposition function, has broad application potential and can be used in many areas to capture tiny changes in position or blockages of components. Besides the watchmaking industry and jewellery manufacturing, as described above, other industries can also benefit from this innovative technology.

For example, the “shaking microscope” with image superposing function may be used in the electronics industry for assembled printed circuit boards and other electronic to determine whether electrical or electronic components have been affixed properly and whether bonding or soldering operations have been completed satisfactorily and reliably. By the identification of loosely seated components or inadequately bonded or soldered components, possible malfunctions and defects can be avoided.

In bearing technology as well, with antifriction bearings, in particular ball bearings, the “shaking microscope” with image superposition function can be used to determine whether certain rolling elements (balls) are “blocked” or not freely movable. A blockage of rolling elements (balls) can lead to friction, wear, and impairment of bearing performance. Early detection of such problems allows the rolling elements concerned to be serviced or replaced in good time, to ensure that the functionality of the antifriction bearing (ball bearing) is maintained.

The wide range of application areas shows that the “shaking microscope” with image superposition function is an extremely versatile and useful technology. The identification of changes in position or blockages of components in various industrial applications can result in improved quality control, greater product reliability and prolonged service life of assemblies in a wide range of industries.

What is claimed is:

1. An apparatus for capturing changes in position of at least one component mounted in an assembly, wherein the apparatus comprises:
at least one vibration generator for subjecting the assembly to vibration movements;
at least one image capturing device for recording images of the same partial or total view of the assembly, in which the at least one component is mounted, before and after the assembly has been subjected to vibration movements;
an image processing device for superposing the images recorded before and after the assembly was subjected to vibration movements; and
an image reproduction device for reproducing the superimposed images with visual highlighting of one or more components that have either undergone changes in position or have not undergone changes in position.

2. The apparatus according to claim 1, further comprising a microscope, wherein the image capturing device is provided in place of a microscope eyepiece or immediately behind a microscope eyepiece to record the magnified images generated by the microscope.

3. The apparatus according to claim 2, wherein the microscope has a carrier unit for the assembly, and wherein the carrier unit is coupled to the vibration generator mechanically, electrically or electromechanically, or the vibration generator is integrated in the carrier unit.

4. The apparatus according to claim 1, further comprising at least one illuminating device for illuminating the partial or total view of the assembly displayed by the image capturing device.

5. The apparatus according to claim 4, wherein the illumination performed by the illuminating device is adjusted in such a way that during superposition of the images, which is carried out by the image processing device and reproduced by the image reproduction device, a black background is created, against which only the image areas that have either undergone changes in position or undergone no changes in position, are highlighted visually as bright image areas.

6. The apparatus according to claim 1, wherein the vibration generator is embodied as a mechanical oscillator, magnetoinductive oscillator, pneumatic oscillator, piezoelectric transducer or electroacoustic transducer.

7. The apparatus according to claim 1, wherein the image capturing device is embodied as a camera, in particular high-resolution digital camera, and the camera is movable in particular to adjust the desired view.

8. The apparatus according to claim 1, wherein the image reproduction device is embodied as a screen, in particular a high-resolution display.

9. A method for capturing changes in position of at least one component mounted in an assembly, wherein the method comprises:
subjecting the assembly to vibration movements;
recording images of the same partial or total view of the assembly in which the at least one component is mounted, before and after the assembly is subjected to vibration movements;
superimposing the images recorded before and after the assembly is subjected to vibration movements; and
reproducing the superimposed images with visual highlighting of one or more components that have either undergone changes in position or have not undergone changes in position.

10. The method according to claim 9, wherein the at least one component visually highlighted in the reproduced superposed images is marked in the assembly, and the at least one marked component subsequently undergoes a post-processing step.

11. The apparatus according to claim 1, wherein the assembly is a watchmakers' artefact, in particular a wristwatch, more particularly a crown device for a wristwatch, and the at least one component is a decorative element, in particular a jewel, more particularly a gemstone, and wherein the decorative element is retained in the watchmakers' artefact by multiple, in particular four, claws.

12. The apparatus according to claim 1, wherein the assembly is an electrical or electronic assembly, in particular an assembled printed circuit board, and the at least one component is an electrical or electronic component, in particular a component mounted on a printed circuit board surface.

13. The apparatus according to claim 1, wherein the assembly is an antifriction bearing and the at least one component is a rolling element of the antifriction bearing.

14. The method according to claim 9, wherein the assembly is a watchmakers' artefact, in particular a wristwatch, more particularly a crown device for a wristwatch, and the at least one component is a decorative element, in particular a jewel, more particularly a gemstone, and wherein the decorative element is retained in the watchmakers' artefact by multiple, in particular four, claws.

15. The method according to claim 14, wherein the assembly is an electrical or electronic assembly, in particular an assembled printed circuit board, and the at least one component is an electrical or electronic component, in particular a component mounted on a printed circuit board surface.

16. The method according to claim 14, wherein the assembly is an antifriction bearing and the at least one component is a rolling element of the antifriction bearing.
